(19) United States
(12) Patent Application Publication
(10) Pub. No.: US 2009/0124222 A1
(43) Pub. Date: May 14, 2009

(54) Radio Receiver

(75) Inventor: Keiji Kobayashi, Kawanishi-shi (JP)

Correspondence Address: OLIFF & BERRIDGE, PLC, P.O. BOX 320850, ALEXANDRIA, VA, 22320-4850, US

(73) Assignees: Sanyo Electric Co., Ltd, Moriguchi-shi (JP); Sanyo Semiconductor Co., Ltd, Ora-gun (JP)

(21) Appl. No.: 12/292,039

(22) Filed: Nov. 10, 2008

(30) Foreign Application Priority Data
Nov. 13, 2007 (JP) 2007-294077

(51) Int. Cl. H03D 5/00

(52) U.S. Cl. 455/142

(57) ABSTRACT

Reducing the cost and size of an FM radio receiver for receiving the North American weather band is aimed. An intermediate-frequency bandpass filter (IFBPF (80)) for limiting the band of a reception signal converted to an intermediate signal is configured with a variable passband width W_{F}. W_{F} is varied in accordance with reception conditions. When the user selects to receive signals in the weather band, a microcomputer (54) switches the tuning frequencies and sets W_{F} to a lower limit of a range variable by the IFBPF (80). Adjacent-channel interference can thereby be suppressed during reception in the weather band, which has a smaller channel step than do other bands. In this configuration, there is no need to externally mount an expensive crystal filter to an IC for an FM tuner.

### CROSS-REFERENCE TO RELATED APPLICATION

The priority application number JP 2007-294077 upon which this patent application is based is hereby incorporated by reference.

### BACKGROUND OF THE INVENTION

1. Field of the Invention

The present invention relates to a radio receiver capable of receiving the weather band in which meteorological information is broadcast in FM in the United States of America.

2. Description of the Prior Art(s)

In the United States of America, the National Oceanic and Atmospheric Administration (NOAA) currently provides meteorological information through FM broadcasts using a frequency range from 162.4 MHz to 162.55 MHz. This frequency range is referred to as the weather band. Seven channels are arranged at 25-kHz intervals in the weather band.

FIG. 2 is a block diagram showing the structure of a conventional FM radio receiver capable of receiving the weather band. An RF (Radio Frequency) signal received by an antenna 2 is mixed with a first local oscillation signal in a first mixing circuit 4, and the RF signal of the target reception channel is converted in frequency to a first intermediate signal S_{IF1} having a predetermined intermediate frequency (intermediate frequency: IF) f_{IF1}.

The frequency of S_{IF1} is limited by a bandpass filter (bandpass filter: BPF) 6 or a BPF 7, and the signal is input to a second mixing circuit 8. For example, BPF 6 may be composed of a ceramic filter CF that has a comparatively wide passband, and BPF 7 may be composed of a crystal filter XF that has a narrow passband width and high selectivity characteristics. Passage of S_{IF1} through either BPF 6 or 7 is switched in accordance with the receiver band. For example, in a general US FM broadcast that uses 87.5 to 108 MHz, BPF 6 (CF) is selected according to the fact that the channel step is 200 kHz. By contrast, BPF 7 (XF) is selected in order to prevent adjacent-channel interference because the channel step of the weather band is narrow.

S_{IF1} that has passed through either BPF 6 or BPF 7 is mixed with a second local oscillation signal in the second mixing circuit 8, and is converted in frequency to a second intermediate signal S_{IF2} having a predetermined intermediate frequency f_{IF2}. S_{IF2} passes through IFBPF 10, which is a BPF whose center frequency is f_{IF2}, and is then FM detected by an FM detection circuit 12. An audio signal is reproduced on the basis of the FM detection output S_{DET}.

IFBPF 10 may, for example, be formed on a common semiconductor chip that also has mixing circuits 4, 8, an FM detection circuit 12, a bandwidth control circuit 20, and the like as part of an IC for an FM tuner.

BPF 7, which is used to receive signals in the weather band, is composed of a crystal filter as mentioned above. The crystal filter is comparatively expensive and creates the problem of increasing the manufacturing cost of the radio receiver. Also, a crystal filter cannot be incorporated into an IC used for FM tuners and is an externally mounted part. The resulting problem is that the number of parts is increased and it becomes difficult to reduce the size of the radio receiver.

### SUMMARY OF THE INVENTION

An object of the present invention is to reduce the price and size of a radio receiver used to receive signals in the weather band.

The radio receiver according to the present invention has an intermediate signal generating circuit for performing a frequency conversion in which the carrier frequency of a target reception channel for a reception signal is shifted to a predetermined intermediate frequency, and generating an intermediate signal; a variable bandpass filter for transmitting the intermediate signal of the target reception channel, the filter being capable of variably setting the passband width between a predetermined lower width limit and a predetermined upper width limit; and a bandwidth control circuit for variably controlling the passband width of the variable bandpass filter, wherein the bandwidth control circuit fixedly sets the passband width of the variable bandpass filter to the lower width limit in cases where the target reception channel is set to the weather band.

### BRIEF DESCRIPTION OF THE DRAWINGS

FIG. 1 is a schematic block composition diagram of a radio receiver according to the present invention; and

FIG. 2 is a block diagram showing the structure of a conventional FM radio receiver capable of receiving the weather band.

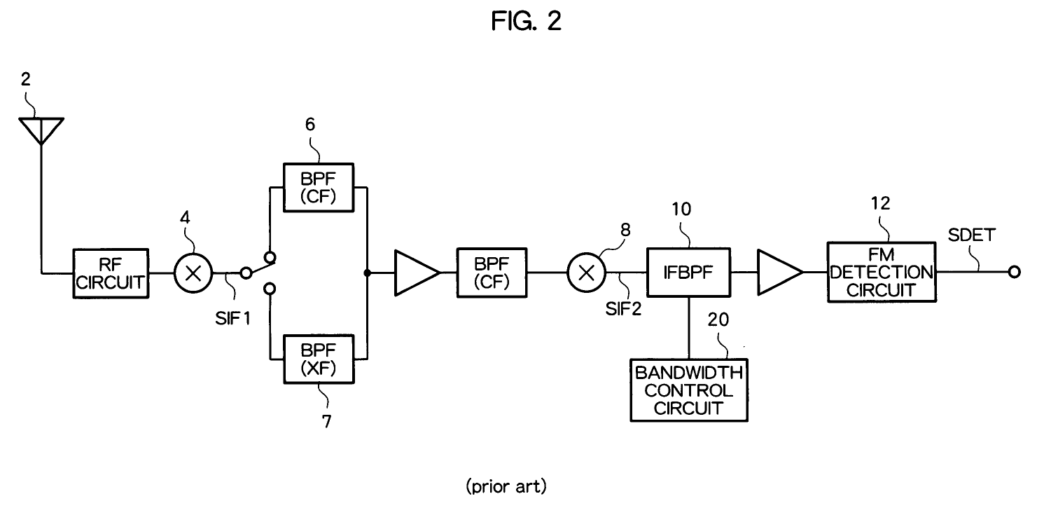

### DESCRIPTION OF THE PREFERRED EMBODIMENT(S)

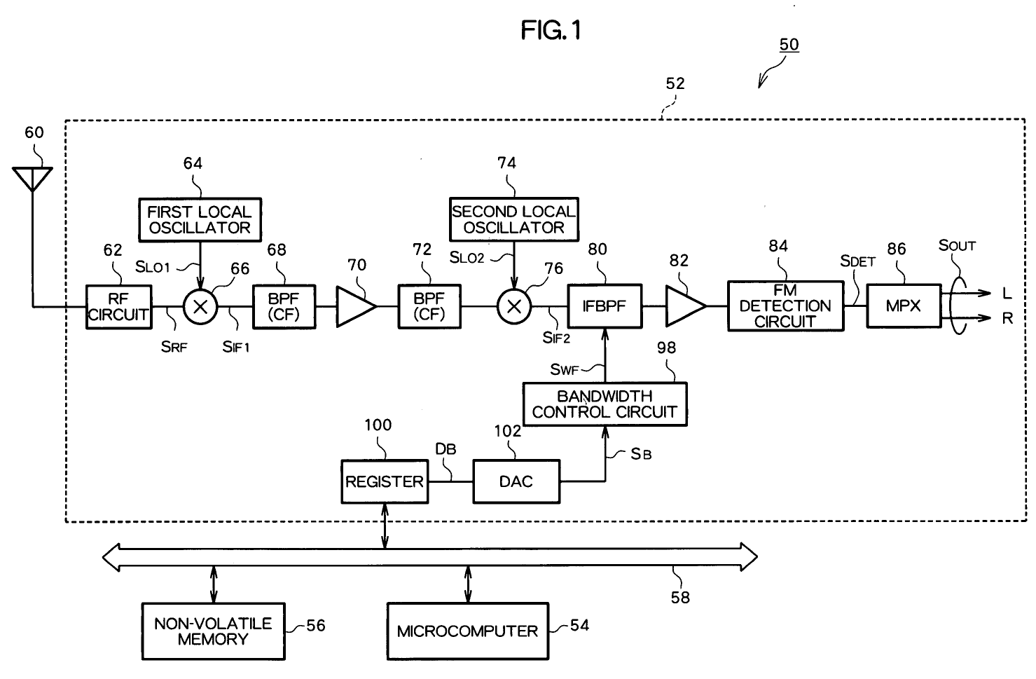

Following is a description of embodiments of the present invention on the basis of diagrams. FIG. 1 is a schematic block diagram of an FM radio receiver 50 according to the embodiment. The FM radio receiver 50 has an FM tuner circuit 52, a microcomputer 54, a non-volatile memory 56 such as EEPROM (Electronically Erasable and Programmable Read Only Memory) or the like, and a system bus 58 for allowing communication to be performed between the components. The principal part of the FM circuit 52 is an IC.

An RF signal S_{RF0} received by an antenna 60 is processed by a signal processing system that includes an RF circuit 62, a first local oscillator 64, a first mixing circuit 66, BPF 68 and 72, a buffer amp 70, a second local oscillator 74; a second mixing circuit 76, an IFBPF 80, a limiter amp 82, an FM detection circuit 84, and a matrix circuit (MPX) 86, and an output signal S_{OUT} is generated.

The FM tuner circuit 52 has a bandwidth control circuit 98, a register 100, and a D/A convertor (DAC) 102 in addition to the constituent elements described above.

The RF signal S_{RF0} is input into the RF circuit 62. The RF circuit 62 performs a tuning process for extracting an RF signal S_{RF} having a relatively narrow band, which includes a target reception station having a carrier frequency f_{R}, from the RF signal S_{RF0} that spans the band in which signals are received. The RF signal S_{RF} extracted by the RF circuit 62 is input into the first mixing circuit 66.

The first local oscillator 64 has an oscillating circuit which uses a PLL (Phase Locked Loop) circuit, and a frequency dividing circuit, and outputs a first local oscillation signal S_{LO1}.

The first mixing circuit 66 mixes the input RF signal S_{RF} with the first local oscillation signal S_{LO1} that is input from the first local oscillator 64, and a first intermediate signal S_{IF1} is generated. The frequency f_{LO1} of S_{LO1} is adjusted so that the carrier frequency f_{R} of the signal of the target reception station included in S_{RF} is converted to the predetermined first intermediate frequency f_{IF1} in the frequency conversion of the signal to S_{IF1} by the first mixing circuit 66. This adjustment is performed by a process in which the microcomputer 54 sets data in a register (not shown), and controlling the division ratio of a frequency divider and the oscillation frequency of the oscillating circuit in the first local oscillator 64 on the basis of the data. The first intermediate frequency f_{IF1} may be set to 10.7 MHz, for example.

An S_{IF1} which is output from the first mixing circuit 66 is input to the second mixing circuit 76 via BPF 68, buffer amp 70, and BPF 72. BPF 68 and 72 can be configured using, for example, a ceramic filter CF.

The second mixing circuit 76 mixes the input first intermediate signal S_{IF1} with the second local oscillating signal S_{LO2} which is input from the second local oscillator 74, and a second intermediate signal S_{IF1} having the second intermediate frequency f_{IF2} is generated. The frequency f_{LO2} of S_{LO2} is set to (f_{IF1}-f_{IF2}), and the target reception signal having the frequency f_{IF1} is converted to the frequency f_{IF2} in the second mixing circuit 76. The second intermediate frequency f_{IF2} may, for example, be set to 450 kHz.

S_{IF1} is input to IFBPF 80. IFBPF 80 is a bandpass filter in which the central frequency is f_{IF2} and in which the passband width W_{F} can be variably set. The passband width W_{F} of IFBPF 80 is controlled by the bandwidth control circuit 98. W_{F} is variable within the range of 40 to 220 kHz. The passband width W_{F} of IFBPF 80 is set to 40 kHz, which is the minimum bandwidth in the weather band.

S_{IF2} which is output from IFBPF 80 passes through the limiter amp 82 and is input into the 1M detection circuit 84. The FM detection circuit 84 may comprise, for example, a quadrature detection circuit. The FM detection circuit 84 performs FM detection of the S_{IF2} that is input from the limiter amp 82, and outputs a detected output signal S_{DET}.

The matrix circuit 86 extracts an (L+R) signal and an (L−R) signal from S_{DET}, which is a stereo-composite signal, during a stereo broadcast; separates a left signal and a right signal from the (L+R) signal and (L−R) signal; and outputs those signals as S_{OUT}.

An analog voltage signal S_{B}, which is generated by the D/A convertor 102 on the basis of the data D_{B} stored in the register 100, is input into the bandwidth control circuit 98. Data D_{B} is set in the register 100 by the microcomputer 54. When the user of the FM radio receiver 50 switches the reception channel to the weather band, the microcomputer 54 controls the first local oscillator 64 as described above, performs a process such as one in which the frequency f_{LO1} of the first local oscillating signal S_{LO1} is switched to a value corresponding to a selected channel of the weather band, and rewrites the data D_{B} stored in the register 100 to a predetermined value d_{WB}. Conversely, when the user issues an instruction to switch from the weather band to a different band, the data D_{B} is rewritten to a predetermined value d_{OB}. It is possible, for example, to adopt an arrangement in which d_{WB} and d_{OB} are stored in the memory 56 in advance, and the microcomputer 54 reads the data and stores the data in the register 100 in a processing program for switching channels.

The bandwidth control circuit 98 generates a control voltage signal S_{WF} for IFBPF 80 on the basis of the signal S_{B} that is output by the D/A convertor 102.

Specifically, the bandwidth control circuit 98 sets the passband width W_{F} according to the reception field intensity, presence or absence of adjacent-channel interference, and other reception conditions in a state in which a signal S_{B} that corresponds to the data d_{OB} is input from the D/A convertor 102.

The control circuit 98 sets W_{F} to the lower limit of variability for IFBPF 80 on the basis of the signal S_{B} in a state in which the signal S_{B} that corresponds to the data d_{WB} is input from the D/A convertor 102, that is, in a state in which the weather band is being received. This control can be performed irrespective of the reception state determined based on the other input signals S_{M-DC}, S_{AI}, and S_{MD}.

Adjacent-channel interference can thus be suppressed by setting W_{F} to the lower limit value when the weather band, which has a smaller channel step than do other bands, is received. In addition, using an IFBPF 80 that can be incorporated into an IC used for FM tuners makes it possible to suppress adjacent-channel interference, and there is no need to externally mount expensive crystal filters. The FM radio receiver 50 can thereby be produced at a lower cost, and a smaller size can be achieved by reducing the number of parts.

As described above, according to the present invention, adjacent-channel interference can be suppressed by setting the passband width of the variable bandpass filter to the lower variability limit thereof, and a radio receiver can thereby be configured without using a special crystal filter for receiving the weather band. The cost of the radio receiver can thereby be reduced by an amount commensurate with the cost of the unnecessary crystal filter. In addition, there is no need to externally mount a crystal filter to the IC for the FM tuner, and the radio receiver can be made smaller in size and lower in cost.

What is claimed is:

1. A radio receiver capable of receiving a plurality of broadcast bands, including the weather band used in the United States of America to broadcast meteorological information in FM, the radio receiver having:
an intermediate signal generating circuit for performing a frequency conversion in which the carrier frequency of a target reception channel for a reception signal is shifted to a predetermined intermediate frequency, and generating an intermediate signal;
a variable bandpass filter for transmitting the intermediate signal of the target reception channel, the filter being capable of variably setting the passband width between a predetermined lower width limit and a predetermined upper width limit; and
a bandwidth control circuit for variably controlling the passband width of the variable bandpass filter;
wherein the bandwidth control circuit sets the passband width of the variable bandpass filter to the lower width limit in cases where the target reception channel is set to the weather band.

2. The radio receiver according to claim 1, comprising:
the variable bandpass filter being incorporated into a semiconductor integrated circuit provided with the intermediate signal generating circuit and the bandwidth control circuit.

3. The radio receiver according to claim 1, comprising:
the weather band having a plurality of channels that are set at 25-kHz intervals.
